(19) United States
(12) Patent Application Publication
(10) Pub. No.: US 2008/0048798 A1
(43) Pub. Date: Feb. 28, 2008

(54) TRANSMISSION LINE FOR IN-CIRCUIT TESTING

(75) Inventors: Chih-Ming Yang, Taipei (TW); Yen-Hao Chen, Taipei (TW)

Correspondence Address: WORKMAN NYDEGGER, 60 EAST SOUTH TEMPLE, 1000 EAGLE GATE TOWER, SALT LAKE CITY, UT, 84111, US

(73) Assignee: INVENTEC CORPORATION, Taipei (TW)

(21) Appl. No.: 11/466,724

(22) Filed: Aug. 23, 2006

(51) Int. Cl. H03H 7/38

(52) U.S. Cl. 333/34

(57) ABSTRACT

A transmission line used in in-circuit testing point applies the impedance matching concept to optimize the line length and line width of a part of the transmission line where connects to the in-circuit testing point in order to exhibit the high impedance inductance property to approach the impedance matching for the design frequency. Therefore, the discontinuous effect caused by the low impedance property of the capacitive point can be improved.

### BACKGROUND

1. Field of Invention

The present invention relates to a transmission line, and more particularly to a transmission line which is used for in-circuit testing.

2. Related Art

In-circuit testing (ICT) is a test applied to a printed circuit board assembly (PCBA), in which uses a bed of nails to test the efficiency or parameter of a component by contacting the PCB's test nodes regardless of whether other components connecting to the target component.

By testing all components in proper sequence, the ICT can determine whether a component has a correct value in electrical properties such as resistance or capacitance, find out defects occurred in the process such as an open circuit, a short circuit, a device defect or even an integrated circuit damaged by static electricity. Certainly, the original intention of ICT would affect the functional test more. However, after applying a proper electrical design, the unexpected influence of ICT on functional test can be reduced. So that the function could still operate well whether the ICT is applied or not.

An ICT apparatus includes many drivers and detectors. Usually, one driver co-works with one detector for testing a circuit. The driver is used to provide a voltage or current to drive the circuit nodes and enable them to a certain anticipated status. In addition, the driver must be capable to drive the nodes and not to be affected by the circuits around. Also, the driver must have a low enough impedance to enable the circuit measurement without affecting the regular output of the driving node. On the other hand, like other measuring devices, a detector is used for detecting a parameter, so it must have a high enough impedance to enable to not affect the measured circuit.

However, in the PCB production process, in order to increase the reliability and yield rate of a product, the ICT points must be added to the signal line of the circuit of the product. As shown in FIG. 1, it is a schematic diagram 10 showing ICT point 101 added to the transmission line 102 according to a conventional art. The ICT point 101 is used for verifying whether there is an unexpected open circuit or short circuit. Since the ICT point 101 has a low impedance capacitor property, a discontinuous effect to the impedance of the transmission line will be deepen and it further have obvious signal reflection on high speed digital circuit if more ICT points 101 are added to the transmission line 102.

Presently, the discontinuous effect to the impedance of the transmission line is still unable to be reduced. Therefore, in some cases, in order to not affect the signal integrity, the ICT points on the transmission line must be removed. However, a transmission line without the ICT points can not be verified whether there is an unexpected open circuit or short circuit.

### SUMMARY OF THE INVENTION

It is an object of the present invention to provide a transmission line used in the ICT point to improve the discontinuous effect caused by the low impedance property of the capacitive ICT point and the signal return loss under the conditions of without removing the ICT points and increasing cost.

The impedance matching concept based on the Smith Chart is utilized in the transmission line of the present invention. According to the anticipated frequency, the optimized line length and line width are adjusted in a single transmission line so as to change the width of a part of the transmission line connected with the ICT point. Therefore, the part of the transmission line will have a high impedance character, so that it may approach the impedance matching for the design frequency.

Further scope of applicability of the invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given below, which is for illustration only and thus is not limitative of the present invention, wherein:

FIG. 1 is a schematic diagram showing ICT point added to the transmission line according to a conventional art;

FIG. 2 is a schematic diagram showing the line length and line width of a part of the transmission line being changed according to the present invention;

FIG. 3 is a reflection loss graph for both uncompensated testing points and compensated test points according to the present invention; and

FIG. 4 is a diagram for both uncompensated testing points and compensated test points according to the present invention.

### DETAILED DESCRIPTION OF THE INVENTION

The detailed features and advantages of the present invention are discussed in detail in the following embodiments. Anybody skilled in the related arts can easily understand and implement the content of the technology of the invention. Furthermore, the relative objects and advantages of the present invention are apparent to those skilled in the related arts according to the content disclosed in the specification, claims, and drawings.

The present invention makes a part of the transmission line connected with the ICT point exhibit the high impedance property by changing the line width and line length of the transmission line based on the impedance matching concept in order to approach the impedance matching for the design frequency and further improve the discontinuous effect caused by low impedance property of the capacitive ICT point.

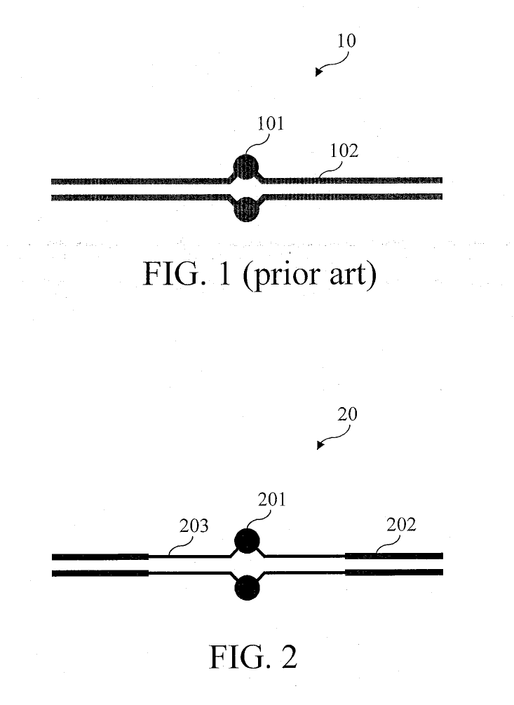

FIG. 2 is a schematic diagram 20 showing the line length and line width of a part of the transmission line 202 being changed according to the present invention. As shown in the FIG. 2, the first line width of the first line section of the transmission line in outer layer of the PCB is similar to that of the transmission line 102 in FIG. 1. Since the impedance of the ICT point 201 does not match that of the line width of the transmission line 102, the line width and line length of the second line section 203 at one end of the ICT point will be changed as a second line length and second line width, respectively. The second line section 203 will connect to the first line section 202 in order to approach the impedance matching for the design frequency. That is, an appropriate line length of the second line section 203 will be taken and the line width of the second line section 203 will be narrowed in order to approach the impedance matching for the design frequency. This embodiment applies the Smith chart to adjust and optimize the line width and line length of a transmission line to approach the impedance matching based on the anticipated frequency. For example, in one embodiment, the anticipated frequency is 2.2 GHz. If the first line width is 5 mil, the second line length and the second line width of the second line section 203 will be 90 mil and 3.5 mil respectively based on the Smith chart, and the second line sections 203 connected to the two ends of the ICT point may not be symmetrical in line length. This method can apply to a single-end transmission circuit and a differential mode transmission circuit at the same time.

The line width of the second line section 203 of a compensation circuit must be narrower than the line width of a regular wire. A narrower width has higher impedance and therefore the inductance is higher. Besides, a longer compensation circuit has a higher inductance, meaning that if the size of ICT point is bigger, the impedance will be lower. Therefore a bigger size of ICT point needs a thinner and longer compensation circuit. Basically, when using a process available thinnest width for approaching the inductance matching, a shortest line length must be used or a longer line length is necessary for providing the compensation inductance.

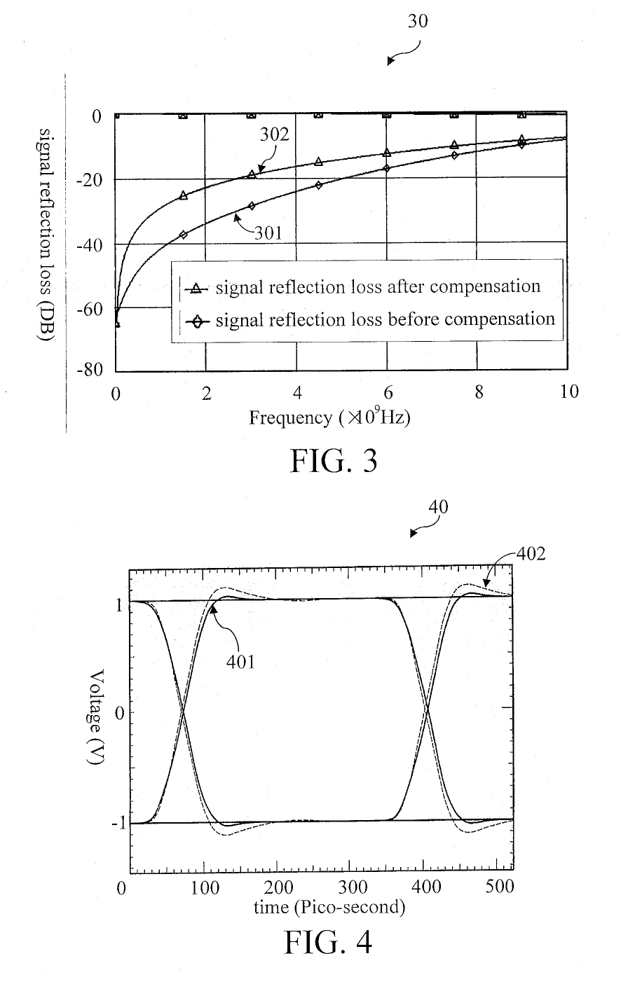

FIG. 3 is a reflection loss graph 30 for both uncompensated testing points and compensated test points according to the present invention, wherein the Smith chart is applied to the differential mode signal of the ICT point to obtain the line length and the line width of the transmission line form the 0 to 10 GHz and to measure the reflection loss curve 301 of the signal which is compensated and the reflection loss curve 302 of the signal which is uncompensated. In the figure, the reflection loss of signals for all frequencies are all improved below 10 GHz frequency, especially between 2 and 5 GHz, where the reflection loss can reduce about 7 db.

FIG. 4 is a diagram for both uncompensated testing points and compensated test points according to the present invention, where the Smith chart is applied to the differential mode signal of the ICT point to obtain the line length and the line width of the transmission line for the 3 GHz and to measure the reflection loss curve 401 of the signals which are compensated and the reflection loss curve 402 of the signals which are uncompensated. As shown in the figure, the eye diagram 402 of uncompensated transmission line has a worse signal.

While the illustrative embodiments of the invention have been set forth for the purpose of disclosure, modifications of the disclosed embodiments of the invention as well as other embodiments thereof may occur to those skilled in the art. Accordingly, the appended claims are intended to cover all embodiments, which do not depart from the spirit and scope of the invention.

What is claimed is:

1. A transmission line used in in-circuit testing (ICT) point, which is disposed on a printed circuit board (PCB) and has one ICT point for circuit testing, wherein the transmission line has a first line section having a first line length and a first line width, the transmission line characterized in:
a second line section having a second line length and a second line width is disposed at a part of the transmission line and located at one side of the ICT point, wherein the second line section connects the ICT point to the first line section.

2. The transmission line as claimed in claim 1, wherein the second line width is narrower than the first line width.

3. The transmission line as claimed in claim 1, wherein the transmission line is used for a single-end transmission.

4. The transmission line as claimed in claim 1, wherein the transmission line is used for a differential mode transmission.

5. The transmission line as claimed in claim 1, wherein the second line length is 90 mil and the second line width is 3.5 mil.
